(19) United States
(12) Patent Application Publication
(10) Pub. No.: US 2007/0284578 A1
(43) Pub. Date: Dec. 13, 2007

(54) ARRAY SUBSTRATE FOR LIQUID CRYSTAL DISPLAY AND METHOD OF TESTING

(75) Inventor: Ji-Hwan Yoon, Suwon-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/752,194

(22) Filed: May 22, 2007

(30) Foreign Application Priority Data
May 22, 2006 (KR) 2006-45796

(51) Int. Cl. H01L 23/58

(52) U.S. Cl. 257/48; 438/12

(57) ABSTRACT

An array substrate including a signal line, a test line to inspect the open of the signal line and fault of the pixels, and a fuse electrically connecting the signal line with the test line. The fuse is opened when a current higher than a reference current is applied thereto. Accordingly, a laser trimming process to insulate the signal line from the test line is not needed after the signal line and pixels have been tested, so that the processing time may be shortened.

### CROSS-REFERENCE TO RELATED APPLICATION

This application relies for priority upon Korean Patent Application No. 2006-45796 filed on May 22, 2006, the contents of which are herein incorporated by reference in its entirety.

### BACKGROUND OF THE INVENTION

1. Field of the Invention

The present invention relates to improving the production of liquid crystal displays and, more particularly, to improving the production of array substrates and a method of testing the same.

2. Description of the Related Art

A liquid crystal display includes an array substrate formed with pixels, a color filter substrate facing the array substrate, and a liquid crystal layer interposed between the array substrate and the color filter substrate.

The pixels are aligned on the array substrate in an array form to provide the liquid crystal layer with pixel voltages. The array substrate includes signal lines which transmit image signals to the pixels. For instance, the array substrate includes data lines and gate lines, which transmit data signals and gate signals, respectively.

In addition, the array substrate is provided with test lines to check whether the signal lines have opens and the pixels have electrical faults. The test lines are electrically connected with the signal lines so as to provide the signal lines with test signals. The test signals are provided to the pixels through the signal lines and the pixels display a predetermined image in response to the test signals.

The inspector can detect whether the signal lines have opens and the pixels have electrical faults by using such a displayed image. That is, if the signal lines have opens or the pixels are not normally formed, the pixels may display an image that does not correspond to the test signal. In contrast, if the signal lines and the pixels normally operate, the pixels display the images corresponding to the test signals.

If the signal lines and the pixel normally operate, a laser is irradiated onto the test lines to open the test line. Thus, the test lines are insulated from the signal lines.

A laser trimming process is performed to cut the test lines after the fault inspection process for the signal lines and the pixels has been finished that may result in an overload, thereby lowering the productivity of the liquid crystal display production process.

### SUMMARY OF THE INVENTION

The present invention provides an array substrate capable of improving productivity of liquid crystal display by shortening the process time.

The present invention also provides a liquid crystal display having the array substrate.

The present invention also provides a method of testing the array substrate.

In one aspect of the present invention, an array substrate includes a base substrate, pixels, at least one signal line, a test line and at least one fuse.

The pixels are formed on the base substrate to display an image. The signal line is formed on the base substrate to transmit an image signal, which corresponds to the image, to the pixels. The test line is formed on the base substrate to transmit a test signal to inspect for opens in the signal line and electric faults in the pixels. The fuse is formed on the base substrate, includes a material different from materials forming the test line and the signal line, and is electrically connected to the test line and the signal line to transmit the test signal from the test line to the signal line. The fuse is opened when a current higher than a predetermined reference current is applied thereto from the test line.

The signal line and the test line include metallic materials and the fuse includes a silicon material.

In another aspect of the present invention, a liquid crystal display includes a first substrate, a second substrate and a liquid crystal layer.

The first substrate is coupled with the second substrate while facing the second substrate. The second substrate includes a base substrate, pixels, at least one signal line, a test line and at least one fuse. The pixels are formed on the base substrate to display an image. The signal line is formed on the base substrate to transmit an image signal, which corresponds to the image, to the pixels. The test line is formed on the base substrate to transmit a test signal to inspect an open of the signal line and electric characteristics of the pixels. The fuse is formed on the base substrate. The fuse includes a material different from a material forming the signal line and is electrically connected to the test line and the signal line to transmit the test signal from the test line to the signal line. The fuse is opened when a current higher than a predetermined reference current is applied thereto from the test line. The liquid crystal layer is interposed between the first and second substrates to control the transmittance of light.

In still another aspect of the present invention, the method of testing an array substrate comprises applying a test signal to a test line through a fuse. The test signal is provided to pixels allowing the pixels to display an image. The displayed image is checked to see whether it corresponds to the test signal. If the displayed image corresponds to the test signal, a current that is higher than a predetermined reference current, is applied to the fuse through the test line, thereby opening the fuse. If the displayed image does not correspond to the test signal, various factors causing the displayed image to be different from the test signal are analyzed.

According to the above, the fuse is opened when the current higher than the reference current is applied thereto. Thus, a laser trimming process, which is performed to insulate the signal line from the test line, can be omitted, so that the process time can be shortened.

### BRIEF DESCRIPTION OF THE DRAWINGS

The above and other advantages of the present invention will become readily apparent by reference to the following detailed description when considered in conjunction with the accompanying drawings, wherein:

FIG. 1 is a plan view illustrating an array substrate according to an exemplary embodiment of the present invention;

FIG. 2 is a sectional view taken along a line I-I′ shown in FIG. 1;

FIG. 3 is a plan view illustrating the array substrate shown in FIG. 1;

FIG. 4 is an enlarged plan view illustrating the area of ‘A’ shown in FIG. 3;

FIG. 5 is a plan view illustrating a data fuse shown in FIG. 4;

FIG. 6 is a sectional view taken along a line II-II′ shown in FIG. 4;

FIG. 7 is an enlarged plan view illustrating the area of ‘B’ shown in FIG. 2;

FIG. 8 is a sectional view taken along a line III-III′ shown in FIG. 7;

FIG. 9 is a sectional view showing a pixel area shown in FIG. 3 according to another exemplary embodiment of the present invention;

FIG. 10 is a sectional view illustrating the connection relationship among the data fuse, the data line and the data test line shown in FIG. 4 according to another exemplary embodiment of the present invention;

FIG. 11 is a sectional view illustrating the connection relationship among the gate fuse, the gate line and the gate test line shown in FIG. 7 according to another exemplary embodiment of the present invention;

FIG. 12 is a plan view illustrating a liquid crystal display according to an exemplary embodiment of the present invention;

FIG. 13 is a sectional view taken along a line IV-IV′ shown in FIG. 12; and

FIG. 14 is a flowchart illustrating a method of testing the array substrate according to an exemplary embodiment of the present invention.

### DESCRIPTION OF THE EMBODIMENTS

Hereinafter, the present invention will be explained in detail with reference to the accompanying the drawings.

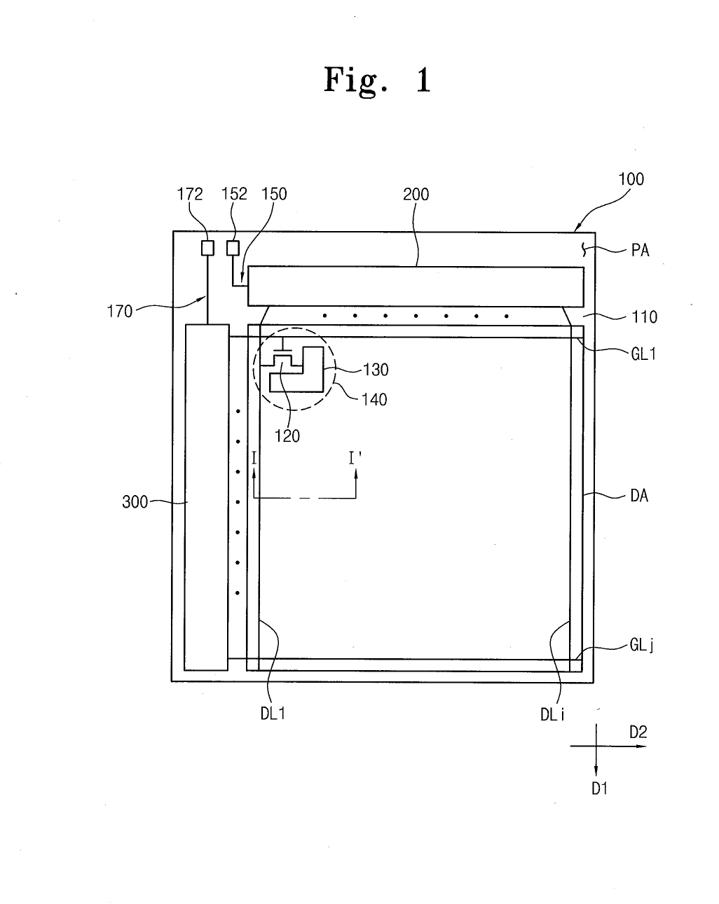

FIG. 1 is a plan view illustrating an array substrate according to an exemplary embodiment of the present invention.

Referring to FIG. 1, the array substrate 100 includes a first base substrate 110, a plurality of data lines DL1, . . . , and DLi, a plurality of gate lines GL1, . . . , and GLj, and a plurality of the pixels 140 and a data test line 150.

The first base substrate 110 includes a material that allows light to pass therethrough, for instance glass, quartz, sapphire or silicon. The first base substrate 110 is divided into a display area DA, in which the image is displayed, and a peripheral area PA, which surrounds the display area DA. The image is not displayed in the peripheral area PA.

The data lines DL1, . . . , and DLi are formed on the first base substrate 110 while extending in the first direction D1. The data lines DL1, . . . , and DLi are aligned in the second direction D2, which is substantially perpendicular to the first direction D1, while being spaced apart from each other. The data lines DL1, . . . , and DLi include a metallic material and first ends of which are electrically connected with a first driver 200, which is mounted on the peripheral area PA. The data lines DL1, . . . , and DLi are connected with pixels 140 so as to provide data signals from the first driver 200 to the pixels 140.

The gate lines GL1, . . . , and GLj are formed on the first base substrate 110, and are aligned in perpendicular to the data lines DL1, . . . , and DLi while being insulated from the data lines DL1, . . . , and DLi. That is, the gate lines GL1, . . . , and GLj extend in the second direction D2 and are spaced apart from each other in the first direction D1. The gate lines GL1, . . . , and GLj include a metallic material and first ends of which are electrically connected with a second driver 300, which is mounted on the peripheral area PA. The gate lines GL1, . . . , and GLj are connected to the pixels to provide the gate signals generated from the second driver 300 to the pixels 140.

The pixels 140 are formed on the display area DA in the first base substrate 110. The pixels 140 are aligned in the form of an array to display the image.

Each pixel 140 includes a thin film transistor (TFT) 120, which is electrically connected to a corresponding data line of the data lines DL1, . . . , and DLi and a corresponding gate line of the gate lines GL1, . . . , and GLj, and a pixel electrode 130, which is electrically connected with the TFT 120.

Hereinafter, the configuration of the TFT 120 and the connection relationship between the TFT 120 and the pixel electrode 130 will be explained in detail.

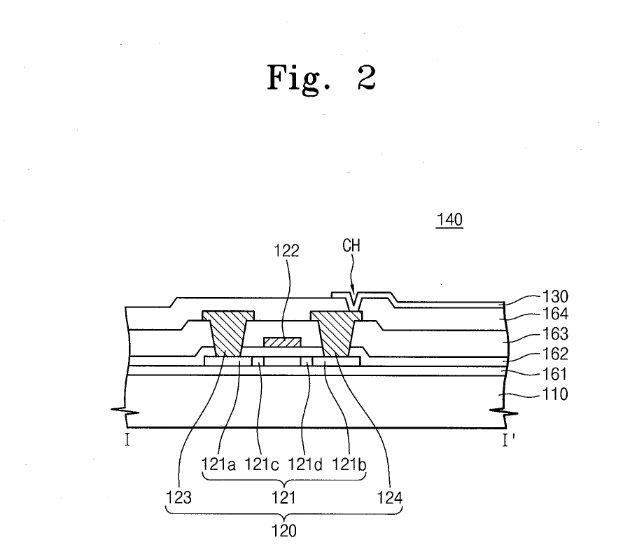

FIG. 2 is a sectional view taken along a line I-I′ shown in FIG. 1.

Referring to FIGS. 1 and 2, the TFT 120 includes a channel layer 121, a gate electrode 122, a source electrode 123 and a drain electrode 124.

The channel layer 121 is formed on the upper part of the first base substrate 110 and includes poly-silicon. The channel layer 121 is provided with areas 121a and 121b, which correspond to the source electrode 123 and the drain electrode 124, respectively, and into which high-density impurities are implanted. Further, the channel layer 121 is provided with areas 121c and 121d, which are formed between an area corresponding to the gate electrode 122 and the areas 121a and 121b, and into which low-density impurities are implanted.

The gate electrode 122 is formed on the upper part of the channel layer 121. The gate electrode 122 extends from the gate line GL1 to receive the gate signal.

The source electrode 123 and the drain electrode 124 are formed on the channel layer 121 where the gate electrode 122 is formed. The source electrode 123 extends from the data line DL1 to receive the data signal. The drain electrode 124 faces the source electrode 123 with the gate electrode 122 interposed therebetween. The drain electrode 124 is electrically connected with the pixel electrode 130 to provide the pixel electrode 130 with the pixel voltage.

The pixel electrode 130 includes a transparent conductive material, for instance, indium tin oxide (ITO) or indium zinc oxide (IZO).

The array substrate 100 further includes a base insulating layer 161, a gate-insulating layer 162, an interlayer dielectric layer 163 and a protective layer 164.

The base insulating layer 161 is formed on the upper surface of the first base substrate 110 and the channel layer 121 is formed on the upper surface of the base insulating layer 161.

The gate-insulating layer 162 is formed on the upper surface of the base insulating layer 161 where the channel layer 121 is formed. The gate-insulating layer 162 is interposed between the channel layer 121 and the gate electrode 122.

The interlayer dielectric layer 163 is formed on the upper part of the gate-insulating layer 162 where the gate electrode 122 is formed. The channel layer 121 is partially exposed through holes, which are formed by partially removing the gate-insulating layer 162 and the interlayer dielectric layer 163. The source electrode 123 and the drain electrode 124 are formed on the upper surface of the interlayer dielectric layer 163 and make contact with the channel layer 121 through the holes.

The protective layer 164 is formed on the interlayer dielectric layer 163. The drain electrode 124 is exposed through a contact hole CH which is formed by partially removing the interlayer dielectric layer 163. The pixel electrode 130 is formed on the protective layer 164 and makes contact with the drain electrode 124 through the contact hole CH.

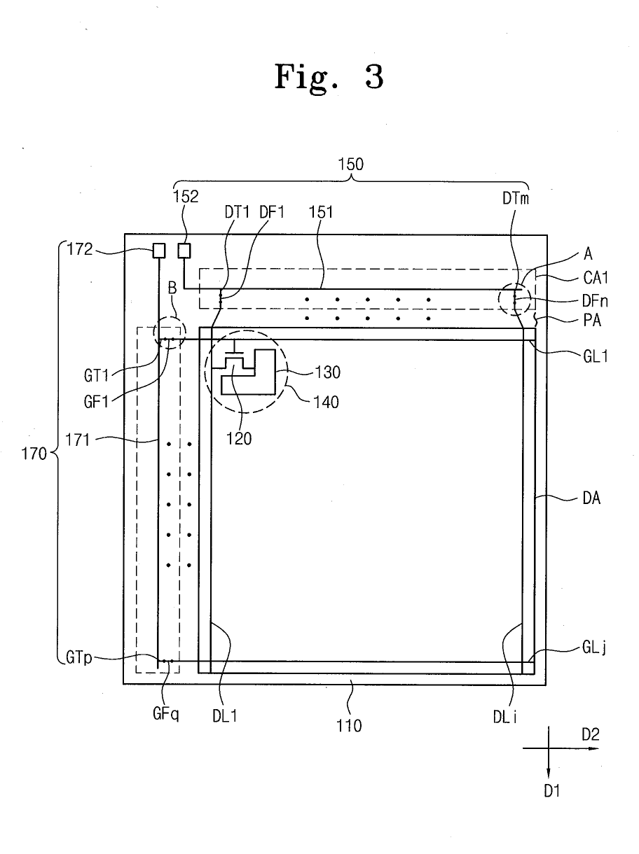

FIG. 3 is a plan view illustrating the array substrate shown in FIG. 1. FIG. 3 represents the array substrate 100 before the first and second drivers 200 and 300 are mounted onto the array substrate 100.

Referring to FIGS. 1 to 3, first ends of the data lines DL1, . . . , and DLi are electrically connected with the data test line 150.

The data test line 150 is formed in the peripheral area PA of the first base substrate 110 and includes a metallic material. The data test line 150 includes a first input line 151, which extends in the second direction D2, and a plurality of data connecting lines DT1, . . . , and DTm, which extend in the first direction D1 from the first input line 151.

The first input line 151 receives a first test signal to provide the first test signal to the data connecting lines DT1, . . . , and DTm. A first input pad 152 is provided at one end of the first input line 151 to which the first test signal is applied. The first input pad 152 is electrically connected with a test device (not shown) that generates the first test signal, and is positioned outside of a first chip area CA1 on which the first driver 200 is mounted.

The data connecting lines DT1, . . . , and DTm are positioned in the first chip area CA1 and in a one-to-one correspondence relationship with the data lines DL1, . . . , and DLi.

The array substrate 100 includes a plurality of data fuses DF1, . . . , and DFn which electrically connect the data lines DL1, . . . , and DLi with the data test line 150.

The data fuses DF1, . . . , and DFn are formed in the first chip area CA1 of the base substrate 110. The data fuses DF1, . . . , and DFn are in a one-to-one correspondence relationship with the data lines DL1, . . . , and DLi.

Hereinafter, the structure of the data fuses DF1, . . . , and DFn and the connection relationship between the data lines DL1, . . . , and DLi and the data test line 150 will be explained with reference to accompanying drawings.

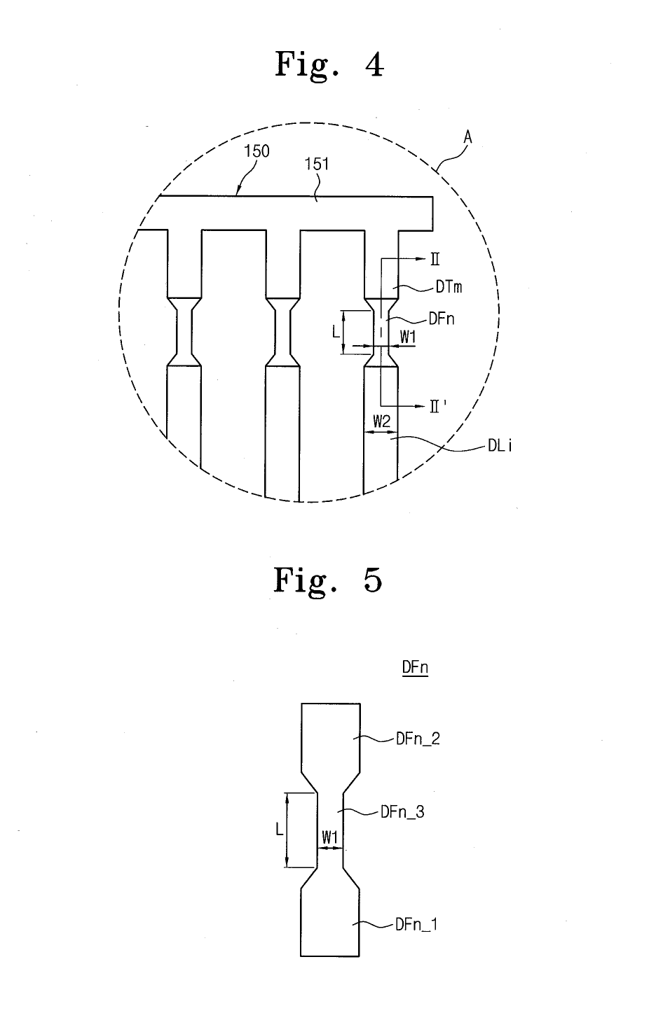

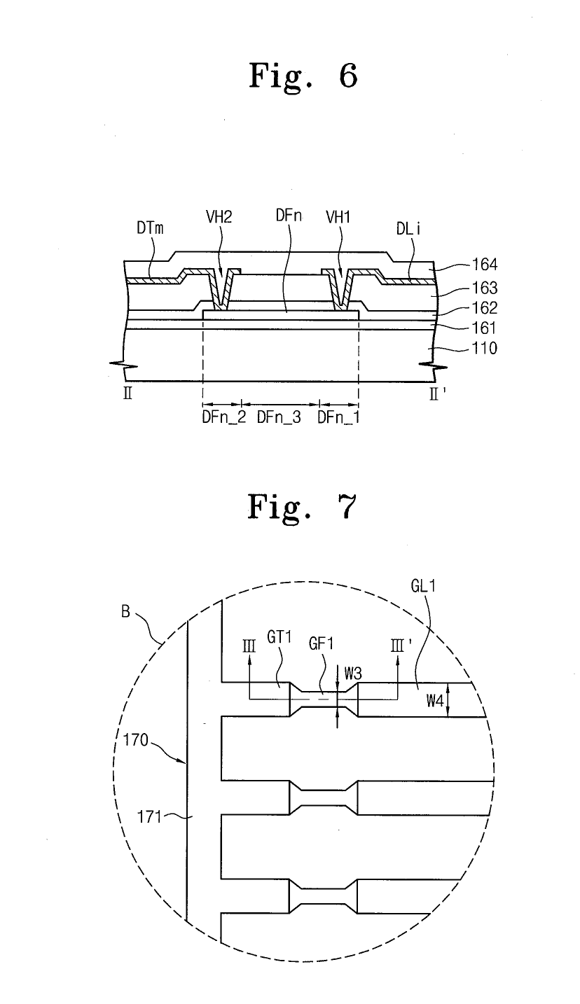

FIG. 4 is an enlarged plan view illustrating the area of ‘A’ shown in FIG. 3, FIG. 5 is a plan view illustrating the data fuse shown in FIG. 4, and FIG. 6 is a sectional view taken along a line II-II′ shown in FIG. 4.

Referring to FIGS. 3 and 4, the data fuses DF1, . . . , and DFn include a poly-silicon material and electrically connect the data lines DL1, . . . , and DLi with data connecting lines DT1, . . . , and DTm.

In the present embodiment, the data fuses DF1, . . . , and DFn have the same structure. In this regard, the nth data fuse DFn will be explained as a representative data fuse in the following description.

Further, in the present embodiment, the connection relationship between the data fuses DF1, . . . , and DFn and the data lines DL1, . . . , and DLi is identical to the connection relationship between the data fuses DF1, . . . , and DFn and the data connecting lines DT1, . . . , and DTm. In this regard, the connection among the nth data fuse, the i^{th} data line DLi and the m^{th} data connecting line DTm will be explained as an example when explaining the connection relationship among data fuses DF1, . . . , and DFn, the data lines DL1, . . . , and DLi and the data connecting lines DT1, . . . , and DTm.

Referring to FIGS. 4 and 5, the nth data fuse DFn includes an output part DFn_1 generating the first test signal, an input part DFn_2 receiving the first test signal and a short part DFn_3 connecting the output part DFn_1 and the input part DFn_2.

In detail, the output part DFn_1 generates the first test signal, which is received through the short part DFn_3, so as to provide the i^{th} data line DLi with the first test signal.

The input part DFn_2 provides the short part DFn_3 with the first test signal received through the m^{th} data connecting line DTm.

The short part DFn_3 provides the output part DFn_1 with the first test signal received through the input part DFn_2.

Referring to FIGS. 4 to 6, the n^{th} data fuse DFn is formed on the upper surface of the base insulating layer 161 formed on the upper surface of the first base substrate 110. Although not shown in FIG. 6, the rest of the data fuses are also formed on the upper surface of the base insulating layer 161.

The process of forming the n^{th} data fuse DFn is identical to the process of forming the channel layer 121 of the thin film transistor 120, and is simultaneously performed with the process of forming the channel layer 121.

The gate-insulating layer 162 and the interlayer dielectric layer 163 are sequentially formed on the upper part of the base insulating layer 161 where the n^{th} data fuse DFn is formed. The first and second via holes VH1 and VH2 are formed by partially removing the gate-insulating layer 162 and the interlayer dielectric layer 163. The output part DFn_1 of the n^{th} data fuse DFn is exposed through the first via hole VH1 and the input part DFn_2 of the n^{th} data fuse DFn is exposed through the second via hole VH2.

The i^{th} data line DLi and the m^{th} data connecting line DTm are formed on the upper surface of the interlayer dielectric layer 163. The i^{th} data line DLi and the m^{th} data connecting line DTm are spaced apart from each other. In this case, the short part DFn_3 of the n^{th} data fuse DFn is exposed through the gap between the i^{th} data line DLi and the m^{th} data connecting line DTm.

The process of forming the i^{th} data line DLi and the m^{th} data connecting line DTm is identical to the process of forming the source electrode 123 and the drain electrode 124, and is simultaneously performed with the process of forming the source electrode 123 and the drain electrode 124.

The i^{th} data line DLi is electrically connected with the output part DFn_1 of the n^{th} data fuse DFn through the first via hole VH1, and the m^{th} data connecting line DTm is electrically connected with input part DFn_2 of the n^{th} data fuse DFn through the second via hole VH2.

Accordingly, the i^{th} data line DLi receives the first test signal generated from the m^{th} data connecting line DTm through the n^{th} data fuse DFn. The i^{th} data line DLi provides the pixels connected with the i^{th} data line DLi with the first test signal, and the pixels display a predetermined image which corresponds to the first test signal. The open of the i^{th} data line DLi and the defect of the pixels connected with the i^{th} data line DLi are detected based on the displayed image.

When the test of the array substrate 100 is finished by using the first test signal, the n^{th} data fuse DFn is open. Thus, the i^{th} data line DLi and the m^{th} data connecting line DTm are insulated from each other.

In detail, when a current that is higher than a first reference current is applied to the n^{th} data fuse DFn from the m^{th} data connecting line DTm, the short part DFn_3 of the n^{th} data fuse DFn is burned to open the n^{th} data fuse DFn. In the present embodiment, the first reference current represents the maximum voltage that allows the short part DFn_3 to be not open, and the maximum voltage of the first test signal is equal to or lower than the first reference current.

An intensity of the current causing the n^{th} data fuse DFn to be burned is determined by the width W1 of the short part DFn_3 of the n^{th} data fuse DFn. The width W1 of the n^{th} data fuse DFn is calculated based on a thermal resistance of the n^{th} data fuse DFn. The thermal resistance is calculated according to equation 1 below.

$$DF\_RC = \frac{DF\_DT}{DF\_P} \qquad EQUATION 1$$

In equation 1, DF_RC is the thermal resistance of the n^{th} data fuse DFn, DF_DT is the temperature difference between the first base substrate 110 and the n^{th} data fuse DFn, and DF_P is power consumption.

Referring to equation 1, the thermal resistance DF_RC of the n^{th} fuse is obtained by dividing the temperature difference DF_DT between the first base substrate 110 and the n^{th} data fuse DFn by the power consumption DF_P.

The temperature difference DF_DT between the first base substrate 110 and the n^{th} data fuse DFn is calculated according to equation 2 below:
DF_{—}DT=TM−TA EQUATION 2

In equation 2, TM is the melting point of the n^{th} data fuse DFn, and TA is the ambient temperature of the n^{th} data fuse DFn.

Referring to equation 2, the temperature difference DF_DT between the first base substrate 110 and the n^{th} data fuse DFn is obtained by subtracting the ambient temperature TA from the melting point TM of the n^{th} data fuse DFn.

The power consumption DF_P of the n^{th} fuse is calculated according to equation 3 below.

$$DF\_P = \frac{( TM - TA ) ⨯ ( DF\_W ⨯ DF\_L )}{\frac{EI\_T}{EI\_C} + \frac{BS\_T}{BS\_C}} \qquad EQUATION 3$$

In equation 3, DF_W is the width W1 of the short part DFn_3, DF_L is the length L of the short part DFn_3, EI_T is the thickness of the insulating layer provided on the lower surface of the n^{th} data fuse DFn, EI_C is the thermal conductivity of the insulating layer provided on the lower surface of the n^{th} data fuse DFn, BS_T is the thickness of the first base substrate 110, and BS-C is the thermal conductivity of the first base substrate 110. In the present embodiment, the insulating layer provided on the lower surface of the n^{th} data fuse DFn is the base insulating layer 161, so EI_T is a thickness of the base insulating layer 161, and EI_C is a thermal conductivity of the base insulating layer 161.

Referring to equation 3, the process of calculating the power consumption DF_P of the n^{th} data fuse DFn is as follows. First, a first value, which is obtained by subtracting the ambient temperature TA of the n^{th} data fuse DFn from the melting point TM of the n^{th} data fuse DFn, is multiplied by a second value, which is obtained by multiplying the width W1 of the short part DFn_3 by the length L of the short part DFn_3, thereby obtaining a third value. The power consumption DF_P of the n^{th} data fuse DFn may be obtained by dividing the third value by a sum of fourth and fifth values in which the fourth value is obtained by dividing the thickness EI_T of the base insulating layer 161 by the thermal conductivity EI_C of the base insulating layer 161 and the fifth value is obtained by dividing the thickness BS_T of the first base substrate 110 by the thermal conductivity BS_C of the first base substrate 110.

In this case, the thermal conductivities BS_C and EI_C of the first base substrate 110 and the base insulating layer 161 are determined according to the materials of the first base substrate 110 and the base insulating layer 161, and the thicknesses BS_T and EI_T of the first base substrate 110 and the base insulating layer 161 are determined according to the size of the array substrate 100. Accordingly, the power consumption DF_P is determined according to the width W1 and the length L of the short part DFn_3.

The width W1 of the short part DFn_3 may be calculated by applying equations 2 and 3 to equation 1 as described below in equation 4.

$$DF\_RC = \frac{( TM - TA )}{\frac{( TM - TA ) ⨯ ( DF\_W ⨯ DF\_L )}{\frac{EI\_T}{EI\_C} + \frac{BS\_T}{BS\_C}}} \\ DF\_RC = \frac{1}{( DF\_W ⨯ DF\_L )} ⨯ [ \frac{EI\_T}{EI\_C} + \frac{BS\_T}{BS\_C} ] \\ DF\_W = [ \frac{1}{DF\_L ⨯ DF\_RC} ] ⨯ [ \frac{EI\_T}{EI\_C} + \frac{BS\_T}{BS\_C} ] \qquad EQUATION 4$$

Referring to equation 4, the fourth value, which is obtained by dividing the thickness EI_T of the base insulating layer 161 by the thermal conductivity EI_C of the base insulating layer 161, is added to the fifth value, which is obtained by dividing the thickness BS_T of the first base substrate 110 by the thermal conductivity BS_C of the first base substrate 110. The width W1 of the short part DFn_3 is obtained by dividing the sum of the fourth and fifth values by the value that is obtained by multiplying the length L of the short part DFn_3 by the thermal resistance DF_RC of the n^{th} data fuse DFn.

Referring to equations 3 and 4, the power consumption DF_P of the n^{th} data fuse DFn may be changed according to the width W1 and the length L of the short part DFn_3. That is, as the width W1 of the short part DFn_3 becomes enlarged, the power consumption DF_P of the n^{th} data fuse DFn may increase, so that the first reference current rises.

If the first reference current is higher than the maximum current of the data signal, the i^{th} data line DLi, which is connected with the n^{th} data fuse DFn, may be damaged. In order to prevent the i^{th} data line DLi from being damaged, the short part DFn_3 is formed with the width W1 that allows the short part DFn_3 to be burned by means of the current having the value within a range between the first reference current and the maximum current of the data signal.

Especially, the n^{th} data fuse DFn includes silicon material which is more vulnerable than the metallic material to the current. Accordingly, the n^{th} data fuse DFn may be burned under a current which is lower than the current that causes the i^{th} data line DLi and the m^{th} data connecting line DTm to be burned. Accordingly, even if the n^{th} data fuse DFn is burned, the m^{th} data connecting line DTm and the i^{th} data line DLi may not be damaged.

In the present embodiment, the short part DFn_3 is formed with the width W1, which is narrower than or equal to the width W2 of the i^{th} data line DLi. Further, the output part DFn_1 and the input part DFn_2 are formed with the width that is wider than or equal to the width W1 of the short part DFn_3.

Although only the n^{th} data fuse DFn has been described above as a representative example, other data fuses also have the same function, structure and the size as those of the n^{th} data fuse DFn. Accordingly, the short part DFn_3 of each data fuse is formed with the width identical to the width of the short part DFn_3 of the n^{th} data fuse DFn, and is open through the same procedure as that of the short part DFn_3 of the n^{th} data fuse DFn.

As described above, the data fuses DF1, . . . , and DFn are burned when the current which is higher than the first reference current is applied to the data fuses DF1, . . . , and DFn, so that the data fuses DF1, . . . , and DFn are opened. Accordingly, the data lines DL1, . . . , and DLi and the data test line 150 are insulated from each other. In this manner, the laser trimming process, which is performed to open the data test line 150, may be omitted in the process of manufacturing the array substrate 100, so that the manufacturing time is shortened and productivity improved.

Referring again to FIG. 1, the first driver 200 is mounted on the first chip area CA1 (referring to FIG. 3) after the data fuses DF1, . . . , and DFn are opened.

The array substrate 100 further includes a gate test line 170 that generates the second test signal to test whether the gate lines GL1, . . . , and GLj are open and the pixels 140 have any electrical abnormality.

The gate test line 170 is formed in the peripheral area PA of the first base substrate 110 and includes a metallic material. The gate test line 170 includes a second input line 171 that extends in a first direction D1 and a plurality of gate connecting lines GT1, . . . , and GTp that extend from the second input line 171 in a second direction D2.

The second input line 171 is positioned in the second chip area CA2 where the second driver 300 is mounted. A second input pad 172 is formed at one end of the second input line 171 to receive the second test signal. The second input pad 172 is electrically connected with a test device (not shown) which generates the second test signal, and is positioned outside of the second chip area CA2 on which the second driver 300 is mounted. The second input line 171 provides the gate connecting lines GT1, . . . , and GTp with the second test signal received through the second input pad 172.

The gate connecting lines GT1, . . . , and GTp are positioned on the second chip area CA2. The gate connecting lines GT1, . . . , and GTp are electrically connected with the gate lines GL1, . . . , and GLj so as to provide the gate lines GL1, . . . , and GLj with the second test signal. The number of the gate connecting lines GT1, . . . , and GTp and the gate lines GL1, . . . , and GLj are the same as each other. The gate connecting lines GT1, . . . , and GTp are in a one-to-one correspondence relationship with the gate lines GL1, . . . , and GLj.

The array substrate 100 includes a plurality of gate fuses GF1, . . . , and GFq electrically connecting the gate lines GL1, . . . , and GLj with the gate connecting lines GT1, . . . , and GTp.

The gate fuses GF1, . . . , and GFq are formed in the second chip area CA2 of the first base substrate 110. The gate fuses GF1, . . . , and GFq are in a one-to-one correspondence relationship with the gate lines GL1, . . . , and GLj.

Hereinafter, the structure of the gate fuses GF1, . . . , and GFq, and the connection relationship between the gate lines GL1, . . . , and GLj and the second test lines will be described with reference to accompanying drawings.

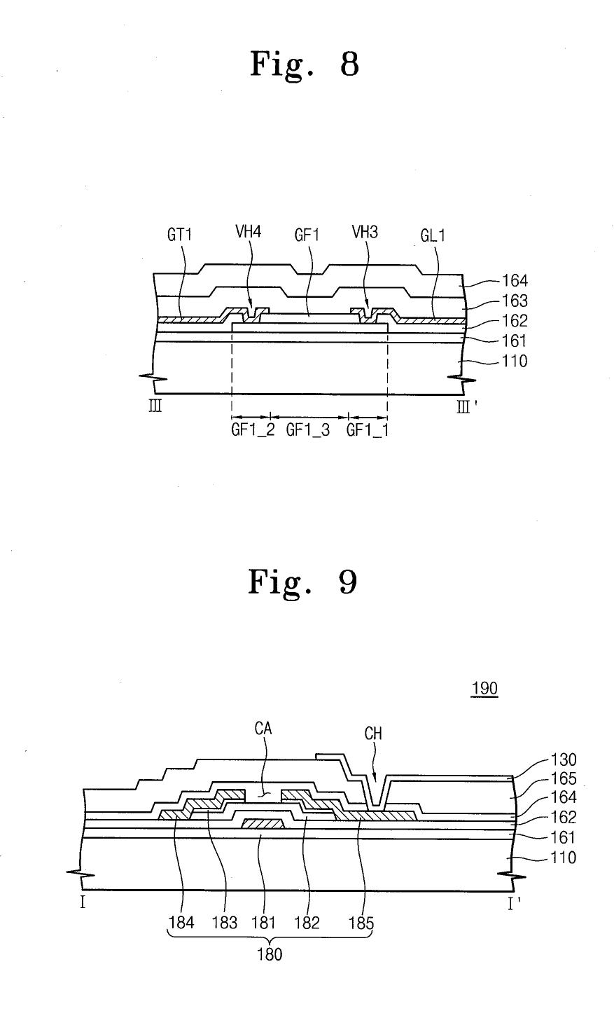

FIG. 7 is an enlarged plan view illustrating the area of ‘B’ shown in FIG. 2, and FIG. 8 is a sectional view taken along a line III-III′ shown in FIG. 7.

Referring to FIGS. 3 and 7, the gate fuses GF1, . . . , and GFq include the poly silicon material, and are positioned between the gate lines GL1, . . . , and GLj and the gate connecting lines GT1, . . . , and GTp so as to be electrically connected to the gate lines GL1, . . . , and GLj and the gate connecting lines GT1, . . . , and GTp. Accordingly, the gate fuses GF1, . . . , and GFq receive the second test signal from the gate connecting lines GT1, . . . , and GTp so as to provide the gate lines GL1, . . . , and GLj with the second test signal.

In the present embodiment, the gate fuses GF1, . . . , and GFq have the same structures as that of the n^{th} data fuse DFn. Accordingly, the detailed description of the gate fuses GF1, . . . , and GFq will be omitted.

Further, in the present embodiment, the connection relationship between the gate fuses GF1, . . . , and GFq and the gate lines GL1, . . . , and GLj is identical to the connection relationship between the gate fuses GF1, . . . , and GFq and the gate connecting lines GT1, . . . , and GTp. Thus, the connection relationship among the first gate fuse GF1, the first gate line GL1 and the first gate connecting line GT1 will be described as a representative example to explain the connection relationship among the gate fuses GF1, . . . , and GFq, the gate lines GL1, . . . , and GLj and the gate connecting lines GT1, . . . , and GTp.

Referring to FIGS. 7 and 8, the process of forming the first gate fuse GF1 is identical to the process of forming the channel layer 121 of the thin film transistor 120, and is simultaneously performed in the process of forming the channel layer 121.

The gate-insulating layer 162 is formed on the upper surface of the base insulating layer 161 where the first gate fuse GF1 is formed. The gate-insulating layer 162 is partially removed to form third and fourth via holes VH3 and VH4. An output part GF1_1 of the first gate fuse GF1 is exposed through the third via hole VH3 and an input part GF1_2 of the first gate fuse GF1 is exposed through the fourth via hole VH4.

The first gate line GL1 and the first gate connecting line GT1 are formed on the upper surface of the gate-insulating layer 162. The process of forming the first gate line GL1 and the first gate connecting line GT1 is identical to the process of forming the gate electrode 122 (see, FIG. 2), and the first gate line GL1 and the first gate connecting line GT1 are simultaneously formed in the process of forming the gate electrode 122.

The first gate line GL1 and the first gate connecting line GT1 are spaced apart from each other by a predetermined distance. In this case, the short part GF1_3 of the first gate fuse GF1 is exposed through the gap between the first gate line GL1 and the first gate connecting line GT1.

The first gate line GL1 is electrically connected with the output part GF1_1 of the first gate fuse GF1 through the third via hole VH3. The first gate connecting line GT1 is electrically connected with input part GF1_2 of the first gate fuse GF1 through the fourth via hole VH4. Accordingly, the first gate line GL1 is electrically connected with the first gate connecting line GT1 through the first gate fuse GF1.

The input part GF1_2 of the first gate fuse GF1 receives the second test signal from the first gate connecting line GT1 so as to provide the output part GF1_1 of the first gate fuse GF1 with the second test signal through the short part GF1_3 of the first gate fuse GF1. The output part GF_11 of the first gate fuse GF1 provides the first gate line GL1 with the second test signal.

The first gate line GL1 provides the second test signal to the pixel connected with the first gate line GL1, so that the pixels connected to the first gate line GL1 display the image corresponding to the second test signal. An opened first gate line GL1 and a fault in the pixels connected to the first gate line GL1 may be detected through the image corresponding to the second test signal.

When the test of the array substrate 100 using the second test signal is finished, the first gate fuse GF1 is opened.

In detail, when a current which is higher than the second reference current is applied to the first gate fuse GF1, the short part GF1_3 of the first gate fuse GF1 is burned open. In this case, the second reference current represents the maximum current that does not cause the short part GF1_3 of the first gate fuse GF1 to open, and the maximum current of the second test signal is lower than or equal to the second reference current.

The value of the current causing the first gate fuse GF1 to burn is determined by a width W3 of the short part GF1_3 of the first gate fuse GF1. In the present embodiment, the procedure of calculating the width W3 of the short part GF1_3 of the first gate fuse GF1 is identical to the procedure of calculating the width W1 of the short part GF1_3 of the n^{th} data fuse DFn (see, FIG. 4). Accordingly, the detailed description thereof will be omitted below.

If the second reference current is higher than the maximum current of the gate signal, the first gate line GL1 which is connected with the gate fuse may be damaged. In order to prevent the first gate line GL1 from being damaged, the short part GF1_3 is formed with a predetermined width W2 such that the short part GF1_3 can be burned when the current within a range of the second reference current to the maximum current of the gate signal is applied to the short part GF1_3.

Especially, the first gate fuse GF1 includes silicon material which is more vulnerable to the current than the metal material. Accordingly, the first gate fuse GF1 may be subject to electric short under a current which is lower than the current that causes the short of the first gate connecting part. Accordingly, even if the first gate fuse GF1 is burned, the first gate connecting line GT1 and the first gate line GL1 may not be damaged.

In the present embodiment, the short part GF1_3 of the first gate fuse GF1 is formed with the width W3 which is narrower than the width W4 of the first gate line GL1 or identical to the width of the first gate line GL1.

Further, the output part GF1_1 and the input part GF1_2 of the first gate fuse GF1 are formed with the width which is equal to or wider than the width W3 of the short part GF1_3.

Although the first gate fuse GF1 has been described above as a representative example, the gate fuses GF1, . . . , and GFq have the same function, structure and the size. Accordingly, the short part GF1_3 of each gate fuse is formed with the width identical to the width of the short part GF1_3 of the first gate fuse GF1, and is open through the same procedure as that of the short part GF1_3 of the first gate fuse GF1.

In this manner, the gate fuses GF1, . . . , and GFq are burned when the current which is higher than the second reference current is applied to the gate fuses, so that the gate fuses GF1, . . . , and GFq are opened. Accordingly, the gate lines GL1, . . . , and GLj and the gate test line 170 are insulated from each other. Thus, the laser trimming process which is performed to open the gate test line 170 may be omitted in the process of manufacturing the array substrate 100, so that the manufacturing time can be shortened. Accordingly, the productivity may be improved.

Referring again to FIG. 1, the second driver 300 is mounted on the second chip area CA2 (see, FIG. 3) after the gate fuses GF1, . . . , and GFq are opened.

The above description has been made based on the pixels 140, data fuses DF1, . . . , and DFn and the gate fuses GF1, . . . , and GFq including poly-silicon. Hereinafter, another embodiment of the present invention in which the array substrate 100 includes amorphous silicon will be described with reference to accompanying drawings.

FIG. 9 is a sectional view illustrating the pixel area shown in FIG. 3 according to another exemplary embodiment of the present invention.

Referring to FIG. 9, the pixel 190 includes a TFT 180 which generates the pixel voltage and a pixel electrode 130 which is electrically connected to the TFT 180.

The TFT 180 includes a gate electrode 181 formed on the base insulating layer 161, an active layer 182 formed on the upper part of the gate electrode 181, an ohmic active layer 183 and the source and drain electrodes 184 and 185 formed on the ohmic active layer 183.

In detail, the gate electrode 181 extends from the gate line that defines the pixel 190.

The gate-insulating layer 162 is formed on the upper surface of the base insulating layer 161 having the gate electrode 181. The active layer 182 including the amorphous silicon is formed on the upper surface of the 10 gate-insulating layer 162. The ohmic active layer 183 is formed on the upper surface of the active layer 182. The ohmic active layer 183 includes n⁺ amorphous silicon. The active layer 182 is exposed through the channel area CA which is formed by partially removing the ohmic active layer 183.

The source electrode 184 and the drain electrode 185 are formed on the upper surface of the ohmic active layer 183. The source electrode 184 extends from the data line defining the pixel 190 (see, FIG. 1). The drain electrode 185 faces the source electrode 184 while interposing the channel area CA therebetween.

A protective layer 164 is formed on the upper surface of the TFT 180, and an organic insulating layer 165 is formed on the upper surface of the protective layer 164. The drain electrode 185 is exposed through the contact hole CH defined by partially removing the protective layer 164 and the organic insulating layer 165.

The pixel electrode 130 is formed on the upper surface of the organic insulating layer 165. The pixel electrode 130 is electrically connected with the drain electrode 185 through the contact hole CH.

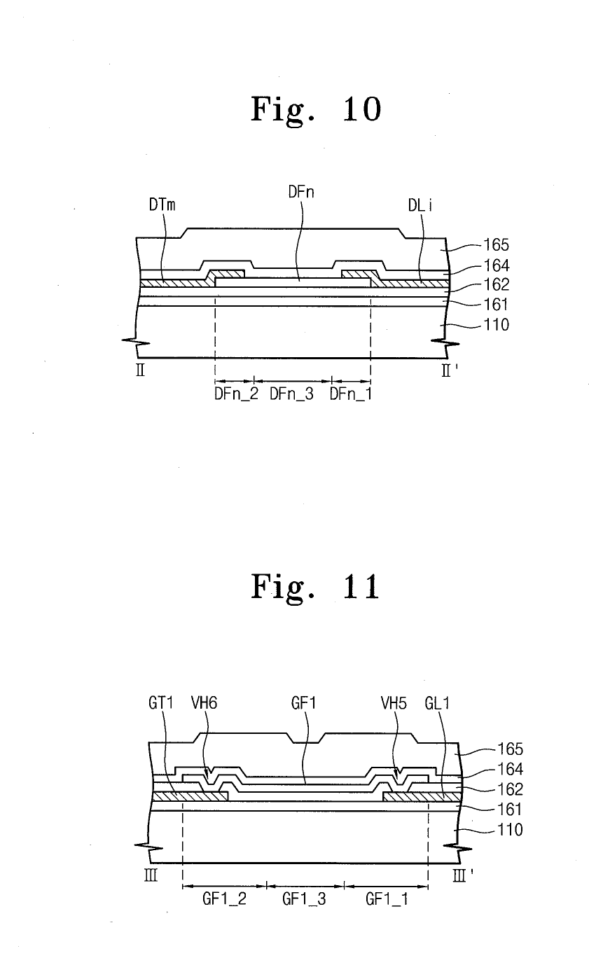

FIG. 10 is a sectional view illustrating the connection relationship among the data fuse, the data line and the data test line shown in FIG. 6 according to another exemplary embodiment of the present invention.

Referring to FIGS. 4 and 10, the data fuses DF1, . . . , and DFn (see, FIG. 3) are connected with the data test line 150 and the data lines DL1, . . . , and DLi.

In the present embodiment, the connection relationship between the data fuses DF1, . . . , and DFn and the data lines DL1, . . . , and DLi is identical to the connection relationship between the data fuses DF1, . . . , and DFn and the data connecting lines DT1, . . . , and DTm. Thus, the connection relationship among the n^{th} data fuse DFn, the i^{th} data line DL1 and the m^{th} data connecting line DT1 will be described as a representative example to explain the connection relationship among the data fuses DF1, . . . , and DFn, the data lines DL1, . . . , and DLi and the data connecting lines DT1, . . . , and DTm.

Further, the n^{th} data fuse DFn shown in FIG. 10 is identical to the n^{th} data fuse DFn shown in FIG. 6, except for the material thereof, so the same reference numeral will be assigned to the n^{th} data fuse DFn and redundant explanation thereof will be omitted below.

The base insulating layer 161 and the gate-insulating layer 162 are sequentially formed on the upper surface of the first base substrate 110.

The n^{th} data fuse DFn including amorphous silicon is formed on the upper surface of the gate-insulating layer 162. The process of forming the n^{th} data fuse DFn is identical to the process of forming the active layer 182, and the n^{th} data fuse DFn and the active layer 182 are simultaneously formed when forming the active layer 182.

The i^{th} data line DLi and the m^{th} data connecting line DTm are formed on the upper surface of the gate-insulating layer 162 where the n^{th} data fuse DFn is formed. One end of the i^{th} data line DLi makes contact with the upper surface of the output part DFn_1 of the n^{th} data fuse DFn. One end of the m^{th} data connecting line DTm makes contact with the upper surface of the input part DFn_2 of the n^{th} data fuse DFn. Thus, the i^{th} data line DLi is electrically connected with the m^{th} data connecting line DTm through the n^{th} data fuse DFn.

The protective layer 164 and the organic insulating layer 165 are sequentially formed on the i^{th} data line DLi and the m^{th} data connecting line DTm.

FIG. 11 is a sectional view illustrating the connection relationship among the gate fuse, the gate line and the gate test line shown in FIG. 7 according to another exemplary embodiment of the present invention.

Referring to FIGS. 7 and 11, a plurality of gate fuses GF1, . . . , and GFq (see, FIG. 3) are connected with the gate test line 170 and a plurality of gate lines GL1, . . . , and GLj.

In the present embodiment, the connection relationship between the gate fuses GF1, . . . , and GFq and the gate lines GL1, . . . , and GLj is identical to the connection relationship between the gate fuses GF1, . . . , and GFq and the gate connecting lines GT1, . . . , and GTp. Thus, the connection relationship among the first gate fuse GF1, the first gate line GL1 and the first gate connecting line GT1 will be described as a representative example to explain the connection relationship among the gate fuses GF1, . . . , and GFq, the gate lines GL1, . . . , and GLj and the gate connecting lines GT1, . . . , and GTp.

Further, the first gate fuse GF1 shown in FIG. 11 is identical to the first gate fuse shown in FIG. 8, except for the material thereof, so the same reference numeral will be assigned to the first gate fuse GF1 and redundant explanation thereof will be omitted below.

The base insulating layer 161 is formed on the upper surface of the first base substrate 110, and the first gate line GL1 and the first gate connecting line GT1 are formed on the upper surface of the base insulating layer 161. The first gate line GL1 is spaced apart from the first gate connecting line GT1 by a predetermined distance.

The gate-insulating layer 162 is formed on the base insulating layer 161 where the first gate line GL1 and the first gate connecting line GT1 are formed. The first gate line GL1 is partially exposed through a fifth via hole VH5 obtained by partially removing the gate-insulating layer 162. The first gate connecting line GT1 is partially exposed through a sixth via hole VH6 obtained by partially removing the gate-insulating layer 162.

The first gate fuse GF1 is formed on the upper surface of the gate-insulating layer 162. The output part GF1_1 of the first gate fuse GF1 is electrically connected with the first gate line GL1 through the fifth via hole VH5. The input part GF1_2 of the first gate fuse GF1 is electrically connected with the first gate connecting line GT1 through the sixth via hole VH6. Thus, the first gate line GL1 is electrically connected with the first gate connecting line GT1 through the first gate fuse GF1, and the gate line receives the second test signal through the first gate fuse GF1.

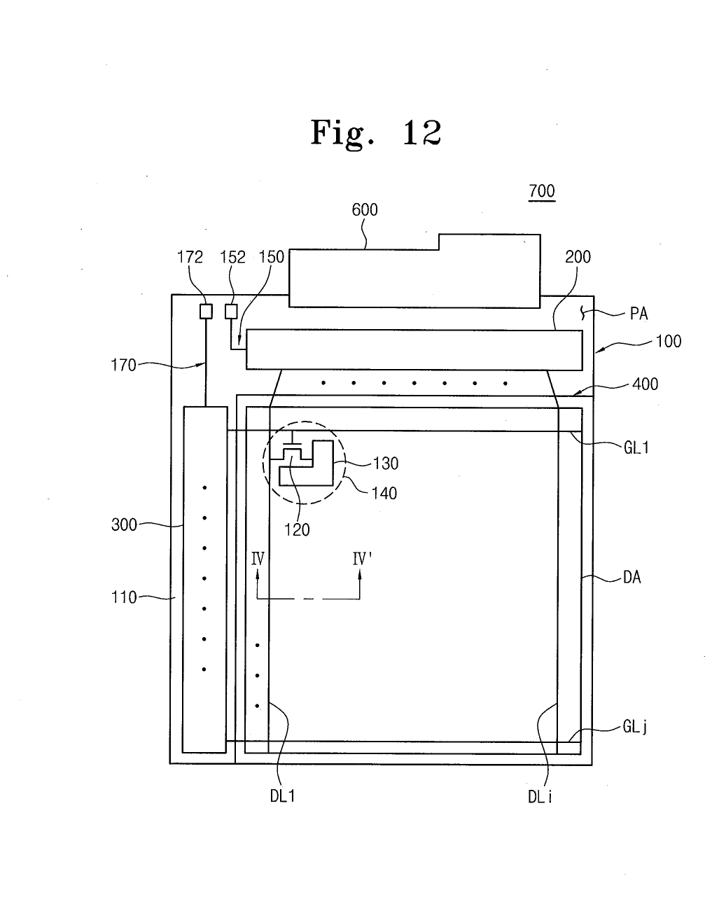

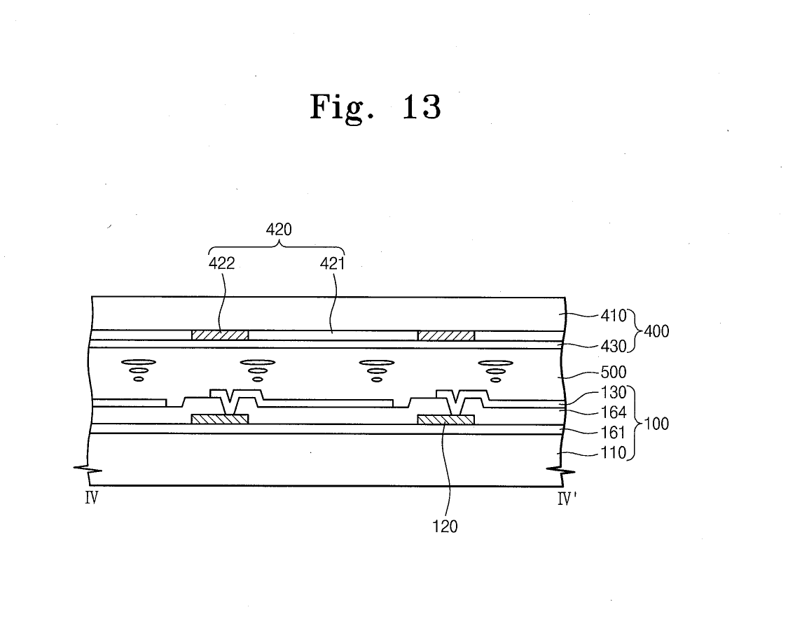

FIG. 12 is a plan view illustrating a liquid crystal display device 700 according to an exemplary embodiment of the present invention, FIG. 13 is a sectional view taken along a line IV-IV′ shown in FIG. 12.

Referring to FIGS. 12 and 13, a liquid crystal display 700 includes the array substrate 100, the first and second drivers 200 and 300, the color filter substrate 400 and the liquid crystal layer 500.

In the present embodiment, the array substrate 100 has a structure which is identical to that of the array substrate shown in FIG. 3, so the same reference numeral will be assigned to the array substrate and redundant explanation thereof will be omitted below.

The array substrate 100 includes a plurality of data lines DL1, . . . , and DLi, a plurality of gate lines GL1, . . . , and GLj, a plurality of pixels 140, a data test line 150, a gate test line 170, a plurality of data fuses DF1, . . . , and DFn (see, FIG. 3) and a plurality of gate fuses GF1, . . . , and GFq (see, FIG. 3).

The data lines DL1, . . . , and DLi receive the data signals from the first driver 200 so as to provide the pixels 140 with the data signals. The gate lines GL1, . . . , and GLj receive the gate signals from the second driver 300 so as to provide the pixels 140 with the gate signals.

The pixels 140 are aligned in an array form. The pixels 140 receive the data signal and the gate signal from the data lines DL1, . . . , DLi and gate lines GL1, . . . , GLj so as to generate the pixel voltage. The pixels 140 provide the liquid crystal layer 500 with the pixel voltage.

The first and second drivers 200 and 300 are provided in the peripheral area PA of the array substrate 100. The first driver 200 generates the data signal corresponding to the image, and the second driver 300 generates the gate signal corresponding to the image.

The color filter substrate 400 is coupled with the array substrate 100, while facing the array substrate 100. The color filter substrate 400 includes a second base substrate 410, a color filter layer 420 and a common electrode 430.

The second base substrate 410 includes a transparent material that allows light to pass therethrough. The color filter layer 420 is formed on the base substrate 410. The color filter layer 420 includes color pixels 421 exhibiting a predetermined color using the light, and a black matrix 422 that surrounds the color pixels 421 to block light leakage from the color pixels 421. The common electrode 430 is formed on the upper surface of the color filter layer 420 to transmit the common voltage.

The liquid crystal layer 500 is interposed between the array substrate 100 and the color filter substrate 400. The liquid crystal layer 500 controls the transmittance of the light according to the electric field formed between the array substrate 100 and the color filter substrate 400. The color filter substrate 400 receives the light controlled by the liquid crystal layer 500 to exhibit a predetermined color. Accordingly, the liquid crystal display device 700 displays the image.

The liquid crystal display 700 further includes an FPC (Flexible Printed Circuit) 600 that generates the image signal corresponding to a predetermined image.

The FPC 600 is attached to the peripheral area PA of the array substrate 100, and is electrically connected with the first driver 200. The FPC 600 provides the first driver 200 with the control signal and the image signal to control the first driver 200.

Hereinafter, the process of testing the open of the data lines DL1, . . . , DLi and gate lines GL1, . . . , and GLj and electric inferiority of pixels 140 will be explained with reference to accompanying drawings.

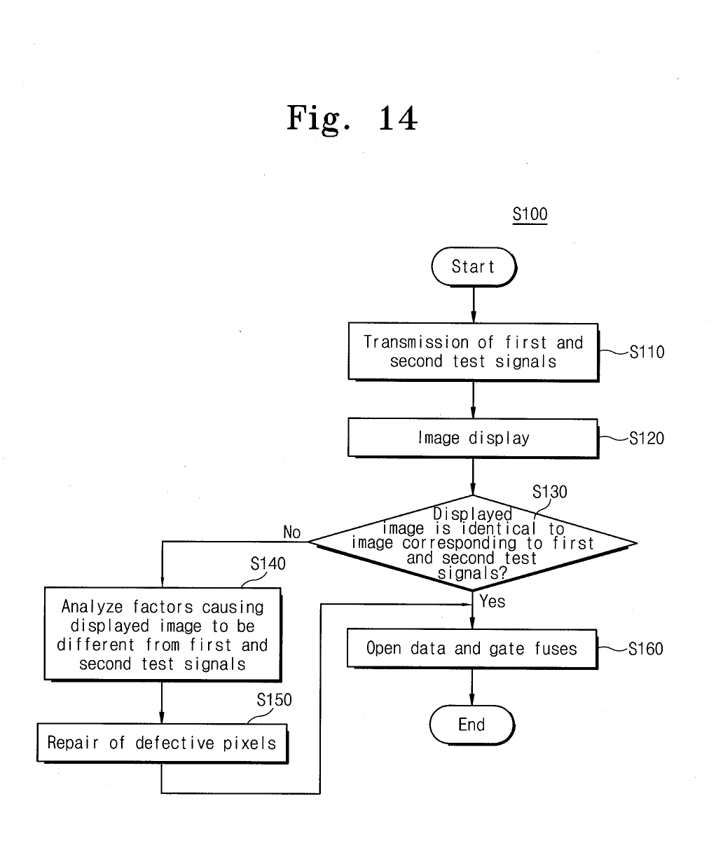

FIG. 14 is a flowchart showing a method of testing the array substrate according to an exemplary embodiment of the present invention.

Referring to FIGS. 3 and 14, the data test line 150 provides the data lines DL1, . . . , and DLi with the first test signal through the data fuses DF1, . . . , and DFn, and the gate test line 170 provides the gate lines GL1, . . . , and GLj with the second test signal through the gate fuse (S110).

The data lines DL1, . . . , and DLi provide the pixels 140 with the first test signal, and the gate lines GL1, . . . , and GLj provide the pixels 140 with the second test signal. Each pixel 140 displays the image corresponding to the first and second test signals (S120).

Then, the displayed image is checked to see whether the displayed image is identical to the image corresponding to the first and second test signals (S130).

If the displayed image is different from the image corresponding to the first and second test signals, the reason causing the different image is analyzed. Thus, the inferior pixels 140 that do not normally display the images may be detected using the displayed image during the manufacturing process and the factor causing the inferior pixels 140 may be detected. In this case, the factors causing the inferior pixels 140 include an open in the data lines DL1, . . . , and DLi and the gate lines GL1, . . . , and GLj connected with the pixels 140 and abnormal formation of the components constituting the pixels 140.

Then, the factor causing the inferior pixels 140 is removed and the inferior pixels 140 are repaired such that the liquid crystal display 700 can properly display the image (S150). For instance, if the factor causing the inferior pixels 140 is an open in the gate lines GL1, . . . , and GLj which are connected with the inferior pixels 140, the opened gate lines GL1, . . . , and GLj are repaired to allow the gate lines to normally transmit the gate signals. That is, a repair line (not shown) used to repair the gate lines GL1, . . . , and GLj and the opened gate lines GL1,...GLj are electrically shorted by using a laser. Accordingly, the gate lines GL1, . . . , and GLj can transmit the gate signal through the repair line, so that the liquid crystal display device 700 can normally display the image.

After the step 150 or in the step 130, if the displayed image is identical to the image corresponding to the first and second test signals, the data fuses DF1, . . . , and DFn and the gate fuses GF1, . . . , and GFq are opened (S160).

That is, the current which is higher than the first reference current is provided to the data fuses DF1, . . . , and DFn through the data test line 150, so that the data fuses DF1, . . . , and DFn are opened. Accordingly, the data test line 150 is insulated form the data lines DL1, . . . , and DLi. Further, the current which is higher than the second reference current is provided to the gate fuses GF1, . . . , and GFq through the gate test line 170, so that the gate fuses GF1, . . . , and GFq are opened. Accordingly, the gate test line 170 is insulated from the gate lines GL1, . . . , and GLj.

In this manner, the method of testing the array substrate 100 (S100) is performed by providing the data and gate test lines 150 and 170 with a current higher than a predetermined reference current after finishing the testing of the array substrate 100, so that the data fuses DF1, . . . , and DFn and gate fuses GF1, . . . , and GFq are opened. According to the present invention, the laser trimming process performed to open the data and gate test lines 150 and 170 may be omitted in the process of manufacturing the array substrate 100, so that the testing time can be shortened.

According to the present invention, the array substrate is provided with the data fuses that electrically connect the data lines with the data test line. When the current which is higher than the first reference current, is applied to the data fuses, the data fuses are opened. Accordingly, the data lines are insulated from the data test lines, so that the laser trimming process performed to open the data test line can be omitted. Accordingly, the manufacturing time can be shortened, so that the productivity may be improved.

In addition, the array substrate is provided with the gate fuses that electrically connect the gate lines with the gate test line. When the current, which is higher than the second reference current, is applied to the gate fuses, the gate fuses are opened. Accordingly, the gate lines are insulated from the gate test lines, so that the laser trimming process performed to open the gate test line can be omitted. Accordingly, the manufacturing time can be shortened, so that the productivity of the liquid crystal display device may be improved.

Although the exemplary embodiments of the present invention have been described, it is understood that the present invention should not be limited to these exemplary embodiments but various changes and modifications may be made by one ordinary skilled in the art within the spirit and scope of the present invention as hereinafter claimed.

What is claimed is:

1. An array substrate comprising:
a base substrate;
pixels formed on the base substrate to display an image;
at least one signal line formed on the base substrate to transmit an image signal, which corresponds to the image, to the pixels;
a test line formed on the base substrate to transmit a test signal to inspect an open of the signal line and electric fault of the pixels; and
at least one fuse formed on the base substrate, wherein the fuse comprises a material different from materials forming the test line and the signal line and is electrically connected to the test line and the signal line to transmit the test signal from the test line to the signal line, the fuse being opened when a current higher than a predetermined reference current is applied thereto from the test line.

2. The array substrate of claim 1, wherein the signal line and the test line comprise metallic materials, and the fuse comprises a silicon material.

3. The array substrate of claim 2, wherein the fuse comprises one of poly-silicon and amorphous silicon.

4. The array substrate of claim 3, wherein the fuse comprises:
an input part electrically connected to the test line;
an output part aligned in opposition to the input part and electrically connected to the signal line; and
a short part connecting the input part with the output part and being opened when the current received from the test line is higher than the reference current.

5. The array substrate of claim 4, wherein the short part of the fuse has a width narrower than a width of the signal line.

6. The array substrate of claim 4, further comprising at least one insulating layer formed on the base substrate.

7. The array substrate of claim 6, wherein the insulating layer is interposed between the base substrate and the fuse, and a width of the short part is obtained by dividing a sum of first and second values by a third value, in which the first value is obtained by dividing a thickness of the fuse and the insulating layer by a thermal resistance value of the insulating layer, the second value is obtained by dividing a thickness of the base substrate by a thermal resistance value of the fuse, and the third value is obtained by multiplying a length of the short part by a thermal resistance value of the fuse.

8. The array substrate of claim 6, wherein the insulating layer is interposed between the signal line and the fuse and between the test line and the fuse.

9. The array substrate of claim 8, wherein
the fuse is interposed between the insulating layer and the base substrate,
the output part is exposed through a first via hole which is formed by partially removing the insulating layer,
the input part is exposed through a second via hole which is formed by partially removing the insulating layer,
the signal line is electrically connected to the output part through the first via hole, and
the test line is electrically connected to the input part through the second via hole.

10. The array substrate of claim 8, wherein
the signal line is interposed between the base substrate and the insulating layer and exposed through a first via hole which is formed by partially removing the insulating layer,
the test line is interposed between the base substrate and the insulating layer and exposed through a second via hole which is formed by partially removing the insulating layer, and
the fuse is formed on the insulating layer and electrically connected to the signal line and the test line through the first and second via holes, respectively.

11. The array substrate of claim 6, wherein
the fuse is formed on the insulating layer,
the signal line is formed on the insulating layer and one end of which makes contact with an upper surface of the output part, and
the test line is formed on the insulating layer and one end of which makes contact with an upper surface of the input part.

12. The array substrate of claim 1, wherein the test line comprises:
an input line extending in a first direction substantially perpendicular to a length direction of the signal line; and
at least one connection line extending from the input line lengthwise along the signal line and being electrically connected with the signal line through the fuse.

13. The array substrate of claim 1, wherein a number of fuses is identical to a number of the signal lines, and the fuses are in a one-to-one correspondence relationship with the signal lines.

14. An array substrate comprising:
a base substrate;
pixels formed on the base substrate to display an image;
at least one data line formed on the base substrate to transmit a data signal, which corresponds to the image, to the pixels;
at least one gate line formed on the base substrate and insulated from the data line to transmit a gate signal which corresponds to the image to the pixels;
a first test line formed on the base substrate to transmit a data test signal to inspect an open of the data line and electric characteristics of the pixels;
at least one first fuse formed on the base substrate, in which the first fuse comprises a material different from a material forming the data line and is electrically connected to the data line and the first test line to transmit the data test signal from the first test line to the data line, the first fuse being opened when a current higher than a predetermined reference current is applied thereto from the first test line;
a second test line formed on the base substrate to transmit a gate test signal to inspect an open of the gate line and electric characteristics of the pixels; and
at least one second fuse formed on the base substrate, in which the second fuse comprises a material different from a material forming the gate line and is electrically connected to the gate line and the second test line to transmit the gate test signal from the second test line to the gate line, the second fuse being opened when a current higher than a predetermined reference current is applied thereto from the second test line.

15. A liquid crystal display comprising:
a first substrate;
a second substrate coupled to the first substrate while facing the first substrate, in which the second substrate comprises a base substrate, pixels formed on the base substrate to display an image, at least one signal line formed on the base substrate to transmit an image signal, which corresponds to the image, to the pixels, a test line formed on the base substrate to transmit a test signal to inspect an open of the signal line and electric characteristics of the pixels, and at least one fuse formed on the base substrate, wherein the fuse comprises a material different from a material forming the signal line and is electrically connected to the test line and the signal line to transmit the test signal from the test line to the signal line, the fuse being opened when a current higher than a predetermined reference current is applied thereto from the test line; and
a liquid crystal layer interposed between the first and second substrates to adjust transmittance of light.

16. A method of testing an array substrate, the method comprising:
applying a test signal to a test line to provide a signal line with the test signal through a fuse;
providing the test signal to pixels through the signal line, thereby allowing the pixels to display an image;
determining whether a displayed image corresponds to the test signal;
providing a current, which is higher than a predetermined reference current, to the fuse through the test line, if the displayed image corresponds to the test signal, thereby opening the fuse; and
analyzing various factors causing the displayed image to be different from the test signal, if the displayed image does not correspond to the test signal.
